(19) United States
(12) Patent Application Publication
(10) Pub. No.: US 2014/0312498 A1
(43) Pub. Date: Oct. 23, 2014

(54) SEMICONDUCTOR DEVICE AND METHOD OF MANUFACTURING SAME

(71) Applicant: Renesas Electronics Corporation, Kawasaki-shi (JP)

(72) Inventors: Michiaki Sugiyama, Kanagawa (JP); Jumpei Konno, Kanagawa (JP)

(73) Assignee: Renesas Electronics Corporation, Kawasaki-shi (JP)

(21) Appl. No.: 14/229,981

(22) Filed: Mar. 30, 2014

(30) Foreign Application Priority Data
Apr. 17, 2013 (JP) 2013-086899

(51) Int. Cl. H01L 23/00; H01L 23/14; H01L 23/15

(52) U.S. Cl. CPC H01L 24/81; H01L 23/15; H01L 23/145
USPC 257/741; 438/125

(57) ABSTRACT

To provide a semiconductor device having improved reliability.

In a wiring board of BGA, an insulation layer has thereon a plurality of bonding leads. The insulation layer is comprised of a prepreg having a glass cloth and a resin layer not having the glass cloth. The prepreg has thereon the resin layer. The bonding leads are arranged directly on the soft resin layer and are therefore supported by this soft resin layer. When a load is applied to each of the bonding leads during flip chip bonding, the resin layer sinks, by which a stress applied to a semiconductor chip can be relaxed.

### CROSS-REFERENCE TO RELATED APPLICATIONS

The disclosure of Japanese Patent Application No. 2013-086899 filed on Apr. 17, 2013 including the specification, drawings and abstract is incorporated herein by reference in its entirety.

### BACKGROUND

The present invention relates to a semiconductor device and a technology of manufacturing same, for example, a technology effective when applied to a semiconductor device obtained by mounting a semiconductor chip on a wiring board by using a flip chip bonding technology.

Japanese Patent Laid-Open No. 2004-165311 (Patent Document 1) describes a structure in which a semiconductor chip is connected with a pad on a chip mounting surface of a board via a metal post.

Japanese Patent Laid-Open No. 2007-329396 (Patent Document 2) describes a structure in which a semiconductor substrate is arranged on a mount board via a metal column and a protruding electrode arranged at the end thereof.

Japanese Patent Laid-Open No. 2009-289908 (Patent Document 3) describes a structure in which electrical connection between the pad of a semiconductor chip and the bonding lead of a wiring board is achieved by gold-solder bonding between a solder formed on a bonding lead and a bump electrode made of gold.
[Patent Document 1] Japanese Patent Laid-Open No. 2004-165311
[Patent Document 2] Japanese Patent Laid-Open No. 2007-329396
[Patent Document 3] Japanese Patent Laid-Open No. 2009-289908 (FIGS. 38 and 39)

### SUMMARY

In flip chip bonding technology, a semiconductor chip is mounted on a wiring board via a columnar (post-like or pillared) conductive member, for example, as described above in Patent Documents 1 and 2 or a semiconductor chip is mounted on a wiring board via a protruding (bump-like) conductive member as described above in Patent Document 3. In flip chip bonding technology, when a semiconductor chip is mounted, a load is applied to the semiconductor chip arranged on a wiring board in a direction perpendicular thereto (in a thickness direction of the wiring board).

There are however variations among electrodes (bonding leads, electrodes with which a conductive member is connected) formed on a chip mounting surface of a wiring board, columnar (post-like) or protruding (bump-like) conductive members to be used for electrically connecting a semiconductor chip with a wiring board, or both the electrodes and the conductive members.

In other words, respective surfaces (surfaces with which conductive members are connected) of electrodes do not always have the same height (in other words, are not always flush with each other) or conductive members do not always have the same height (size) (in other words, are not always flush with each other) due to an influence of variations in processing. When a semiconductor chip is arranged on a wiring board, some of the conductive members fail to contact with the electrodes of the wiring board.

When an insulation layer (an insulation layer with which electrodes come into contact) that supports the electrodes of a wiring board is not a prepreg (a resin layer containing a glass cloth), in other words, is composed of a resin layer not containing a glass cloth (which may also be called “glass fibers”), the insulation layer has hardness (rigidity or strength) lower than that of the prepreg.

As shown in FIG. 25, application of a load to a semiconductor chip 50 sinks a bonding lead 64 of a wiring board 60 with which a bump 52, a conductive member, comes into contact. In other words, application of a load to a resin layer 61 not containing a glass cloth causes deformation of this resin layer 61.

Even if bumps 52 or bonding leads 64 vary in height, this variation in height can be absorbed by sinking of the bonding leads 64 so that a bonding failure between the bumps 52 and the bonding leads 64 can be suppressed.

As described above, on the other hand, the resin layer 61 not containing a glass cloth has a hardness lower than that of a resin layer 66 (prepreg) containing a glass cloth 65 which layer is shown in FIG. 26. A semiconductor device not using a prepreg as a resin layer that supports a wiring layer including the bonding leads 64 is disadvantageous from the standpoint of thinning a semiconductor device.

When the resin layer (prepreg) 66 is employed as an insulation layer that supports electrodes such as bonding leads 64 as shown in FIG. 26, however, it does not easily deform different from the resin layer 61 not containing a glass cloth even if a load is applied to this resin layer 66. The bonding leads 64 formed on this resin layer 66 therefore do not sink. In other words, since the resin layer 66 which is an insulation layer does not easily deform, it is difficult to absorb variations in height among the bumps or bonding leads.

An object of an embodiment disclosed herein is to provide a technology capable of improving the reliability of a semiconductor device.

Other objects and novel features will be apparent from the description herein and accompanying drawings.

A semiconductor device according to one embodiment includes a wiring board having a first insulation layer, a plurality of bonding leads, and a plurality of lands and a semiconductor chip mounted on the wiring board via a plurality of conductive members such that the main surface of the semiconductor chip faces to the wiring board. The conductive members are connected with the bonding leads of the wiring board via a plurality of solder materials, respectively. In the above-mentioned semiconductor device, the first insulation layer is comprised of a first resin layer having glass fibers and a second resin layer having no glass fibers and each of the bonding leads is in contact with the second resin layer.

According to the above-mentioned one embodiment, a semiconductor device having improved reliability can be provided.

### BRIEF DESCRIPTION OF THE DRAWINGS

FIG. 1 is a plan view showing one example of the structure of a semiconductor device according to the embodiment;

FIG. 2 is a cross-sectional view showing one example of the structure taken along a line A-A shown in FIG. 1;

FIG. 3 is a back surface view showing one example of the back surface side structure of the semiconductor device shown in FIG. 1;

FIG. 4 is a plan view showing one example of the upper surface side structure of a wiring board to be incorporated in the semiconductor device shown in FIG. 1;

FIG. 5 is a cross-sectional view showing one example of the structure taken along a line A-A shown in FIG. 4;

FIG. 6 is an enlarged fragmentary cross-sectional view showing one example of the structure of portion B shown in FIG. 5;

FIG. 7 is a back surface view showing one example of the lower surface side structure of the wiring board shown in FIG. 4;

FIG. 8 is a plan view showing one example of the main surface side structure of a semiconductor chip to be mounted on the semiconductor device shown in FIG. 1;

FIG. 9 is a cross-sectional view showing one example of the structure taken along a line A-A shown in FIG. 8;

FIG. 10 is a back surface view showing one example of the back surface side structure of the semiconductor chip to be mounted on the semiconductor device shown in FIG. 1;

FIG. 11 is a cross-sectional view showing one example of the structure taken along a line A-A of FIG. 10;

FIG. 12 is a plan view showing one example of the structure of a wiring board to be used in the fabrication of the semiconductor device shown in FIG. 1;

FIG. 13 is a cross-sectional view showing one example of the structure taken along a line A-A of FIG. 12;

FIG. 14 is a cross-sectional view showing one example of the structure of one device region in the wiring board shown in FIG. 12;

FIG. 15 is a cross-sectional view showing one example of the structure after solder precoating in the fabrication of the semiconductor device shown in FIG. 1;

FIG. 16 is a plan view showing one example of the structure after underfill application in the fabrication of the semiconductor device shown in FIG. 1;

FIG. 17 is a cross-sectional view showing one example of the structure taken along a line A-A in FIG. 16;

FIG. 18 is a cross-sectional view showing one example of the structure after chip mounting in a flip chip bonding step in the fabrication of the semiconductor device shown in FIG. 1;

FIG. 19 is a cross-sectional view showing one example of the structure after pressure bonding of the chip in the flip chip bonding step shown in FIG. 18;

FIG. 20 is a cross-sectional view showing one example of the structure after ball mounting in the fabrication of the semiconductor device shown in FIG. 1;

FIG. 21 is a plan view showing one example of lead arrangement on the upper surface side of a wiring board to be incorporated in a semiconductor device according to Modification Example 1 of the embodiment;

FIG. 22 is a cross-sectional view showing one example of the structure of a semiconductor device according to Modification Example 2 of the embodiment;

FIG. 23 is a cross-sectional view showing one example of the structure of a wiring board to be incorporated in a semiconductor device according to Modification Example 4 of the embodiment;

FIG. 24 is an enlarged fragmentary cross-sectional view showing one example of a wiring board of Modification Example 5 of the embodiment;

FIG. 25 is an enlarged fragmentary cross-sectional view showing a first structure during load application in flip chip bonding investigated by the present inventors; and

FIG. 26 is an enlarged fragmentary cross-sectional view showing a second structure during load application in flip chip bonding investigated by the present inventors.

### DETAILED DESCRIPTION

In the below-described embodiment, descriptions on the same or like parts will essentially be omitted unless particularly necessary.

In the below-described embodiment, a description will be made after divided in plural sections or in plural embodiments if necessary for convenience sake. These plural sections or embodiments are not independent each other, but in a relation such that one is a modification example, details, or complementary description of a part or whole of the other one unless otherwise specifically indicated.

In the below-described embodiment, when a reference is made to the number of elements (including the number, value, amount, range, and the like), the number of elements is not limited to a specific number but may be greater than or less than the specific number unless otherwise specifically indicated or in the case it is principally apparent that the number is limited to the specific number.

Moreover in the below-described embodiment, it is needless to say that the constituting elements (including element steps) are not always essential unless otherwise specifically indicated or in the case where it is principally apparent that they are essential.

In addition, it is needless to say that referring to constituting elements used in the below-described embodiment, the term “is made of A”, “is comprised of A”, “has A”, or “includes A” does not exclude the other elements unless otherwise specifically indicated that the constituting element is limited to only the specific element. Similarly, in the below-described embodiment, when a reference is made to the shape or positional relationship of the constituting elements, that substantially analogous or similar to it is also embraced unless otherwise specifically indicated or principally apparent that it is not. This also applies to the above-described value and range.

The embodiment of the invention will hereinafter be described in detail based on the drawings. In all the drawings for describing the embodiment, members of a like function will be identified by like reference numerals and overlapping descriptions will be omitted. Further, to facilitate understanding of the drawings, even plan views may be sometimes hatched.

### Embodiment

### Semiconductor Device

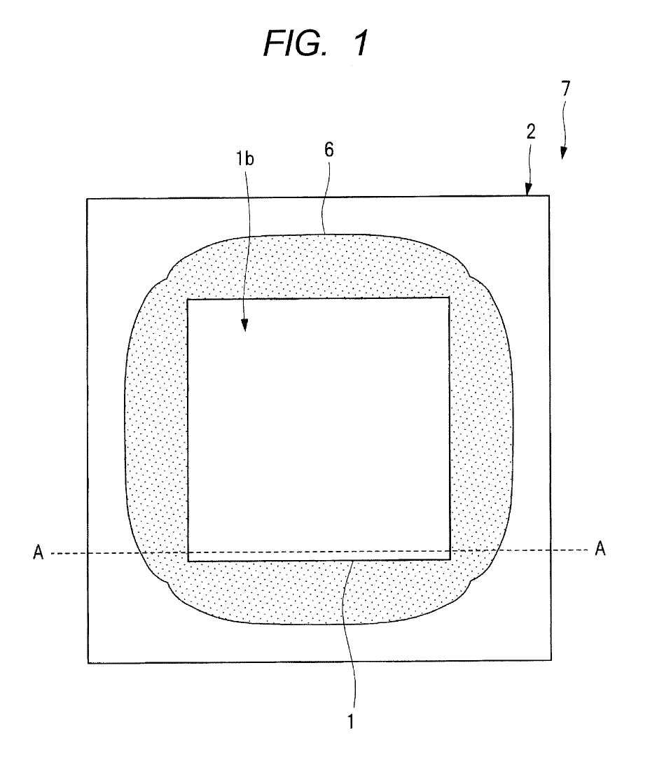

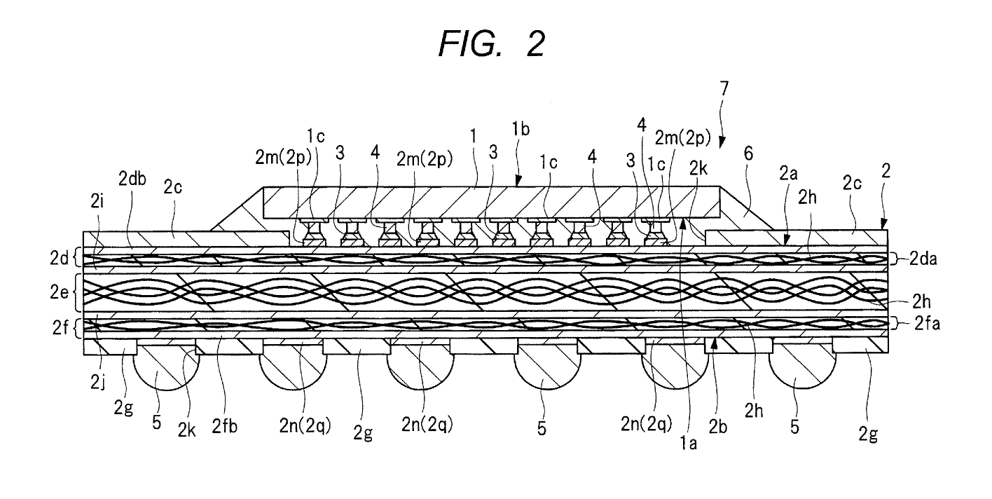

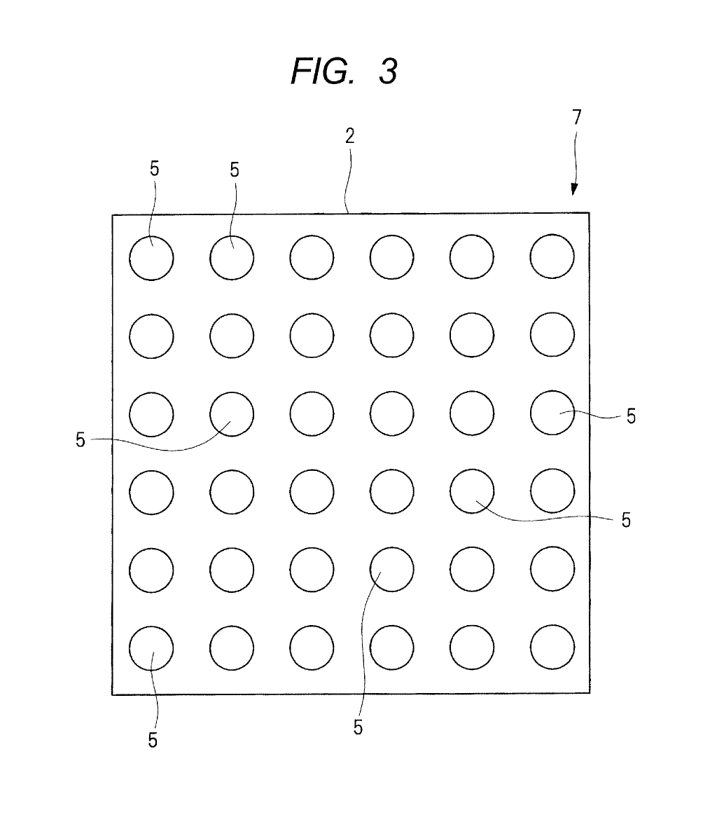

FIG. 1 is a plan view showing one example of the structure of a semiconductor device according to the embodiment; FIG. 2 is a cross-sectional view showing one example of the structure taken along a line A-A shown in FIG. 1; and FIG. 3 is a back surface view showing one example of the back surface side structure of the semiconductor device shown in FIG. 1.

The constitution of the semiconductor device according to the embodiment shown in FIGS. 1 to 3 will next be described. As shown in FIG. 2, the semiconductor device of the present embodiment has a wiring board 2. A semiconductor chip 1 is flip-chip bonded onto this wiring board 2. This means that the semiconductor chip 1 is mounted on an upper surface 2a of the wiring board 2 via a plurality of conductive members such that a main surface 1a of the semiconductor chip 1 faces to an upper surface (chip mounting surface) 2a of the wiring board 2.

On the other hand, the wiring board 2 has, on a lower surface 2b thereof, a plurality of solder balls 5 which will serve as external terminals of the semiconductor device. In the present embodiment, these solder balls 5 are arranged in lattice form in a plan view as shown in FIG. 3.

Accordingly, in the present embodiment, a BGA (ball grid array) 7 will be described as one example of the above-mentioned semiconductor device.

In the BGA 7 according to the present embodiment, a plurality of pads (electrodes) 1c provided on the main surface (element formation surface) la of the semiconductor chip 1 and a plurality of bonding leads (electrodes) 2m provided on the upper surface 2a of the wiring board 2 are electrically connected with each other via conductive members and solder materials (connection members) 3, respectively.

In the BGA 7 according to the present embodiment, the pads 1c of the semiconductor chip 1 have thereon the conductive members. In the present embodiment, the BGA 7 using a copper (Cu) pillar 4 as the conductive members will be described. The copper pillars 4 are each made of a material composed mainly of copper and at the same time, they are columnar (post-like) electrodes. The semiconductor chip 1 is therefore flip chip connected with the wiring board 2 via these copper pillars 4 formed respectively on the surfaces of the pads 1c on the main surface 1a of the semiconductor chip. In the flip chip bonding, the copper pillars 4 are electrically connected with the bonding leads 2m of the wiring board 2, respectively, via the solder materials 3 respectively arranged on the end surfaces (surfaces opposite to the bonding leads 2m) of the copper pillars.

As the solder materials 3 described herein, so-called lead-free solder substantially free from lead (Pb) is preferred. It is, for example, a tin-silver (Sn—Ag) solder.

Using such a material makes it possible to cope with an environmental pollution problem. The term “lead-free solder” means a solder having a content of lead (Pb) not greater than 0.1 wt %. This content has been determined as the standard of RoHS (restriction of hazardous substances) instruction.

In the BGA 7, on the side of the upper surface 2a of the wiring board 2, a space formed between the semiconductor chip 1 and the wiring board 2 is filled with an underfill 6 which is a molding resin, as shown in FIG. 2. This underfill 6 is, for example, an epoxy resin and the space is filled with it so as to ensure connection reliability between the semiconductor chip 1 and the wiring board 2.

The underfill 6 also covers the side surface of the semiconductor chip 1. This makes it possible to protect a flip-chip connection (a connection between the copper pillar 4 and the bonding lead 2m) and in addition, to prevent penetration of water from the outside (periphery) of the semiconductor chip 1 to the flip chip connection. A back surface 1b of the semiconductor chip 1 is however exposed, as shown in FIGS. 1 and 2, while being directed toward the upper portion of the BGA 7.

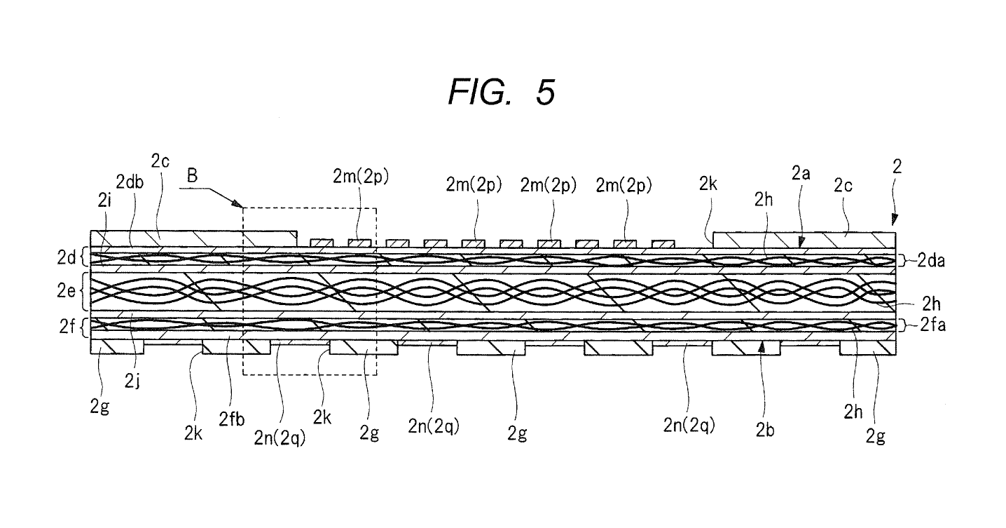

The wiring board 2 is, as shown in FIG. 2, a multilayer wiring board having a plurality of wiring layers. Described specifically, a core layer 2e has, on the surface and back surface thereof, a wiring layer 2i and a wiring layer 2j and as shown in FIG. 5, an uppermost wiring layer 2p has the bonding leads 2m for flip chip connection. On the other hand, a lowermost wiring layer 2q has therein a plurality of lands (electrodes) 2n for connecting therewith the solder ball (conductive member) 5 which is an external terminal of the BGA 7.

This means that the upper surface 2a and the lower surface 2b of the wiring board 2 have thereon solder resist films 2c and 2g, which are insulation films, respectively. On the side of the upper surface 2a, the solder resist film 2c has, in an opening portion 2k thereof, the bonding leads 2m, while on the side of the lower surface 2b, the solder resist films 2g have, in a plurality of opening portions 2k thereof, lands 2n, respectively.

In the wiring board 2 of the present embodiment, on the side of the upper surface 2a, the bonding leads 2m are arranged on an insulation layer 2d. This insulation layer 2d is comprised of a prepreg (resin layer) 2da having a glass cloth (glass fibers) 2h and a resin layer 2db not having the glass cloth 2h. More specifically, the resin layer 2db is formed (stacked) on the prepreg 2da (surface on the side of the semiconductor chip 1).

Accordingly, each of the bonding leads 2m contacts with the resin layer 2db and are arranged on this resin layer 2db. Further, the bonding leads 2m are connected with the copper pillars 4 via the solder materials 3, respectively, so that the prepreg 2da and each of the copper pillars 4 have therebetween the resin layer 2db.

When the prepreg 2da having the glass cloth 2h and the resin layer 2db not having the glass cloth 2h are compared, the prepreg 2da has greater (higher) hardness and greater rigidity. This means that the prepreg 2da having the glass cloth 2h is hard, while the resin layer 2db not having the glass cloth 2h is soft.

The each of bonding leads 2m contacts with the soft resin layer 2db (layer not containing a glass cloth) without having therebetween the prepreg 2da containing the glass cloth (glass fibers) 2h.

As described above, in the wiring board 2 of the BGA 7, the prepreg 2da have thereon the bonding leads 2m via the soft resin layer 2db so that application of a load by flip chip connection or the like causes deformation of the resin layer 2db and sinking of the bonding leads 2m. Even if variations in height occur among the copper pillars 4, all the copper pillars 4 can therefore be connected with the bonding leads 2m. In short, even the copper pillar 4 having a low height can be connected with the bonding lead 2m.

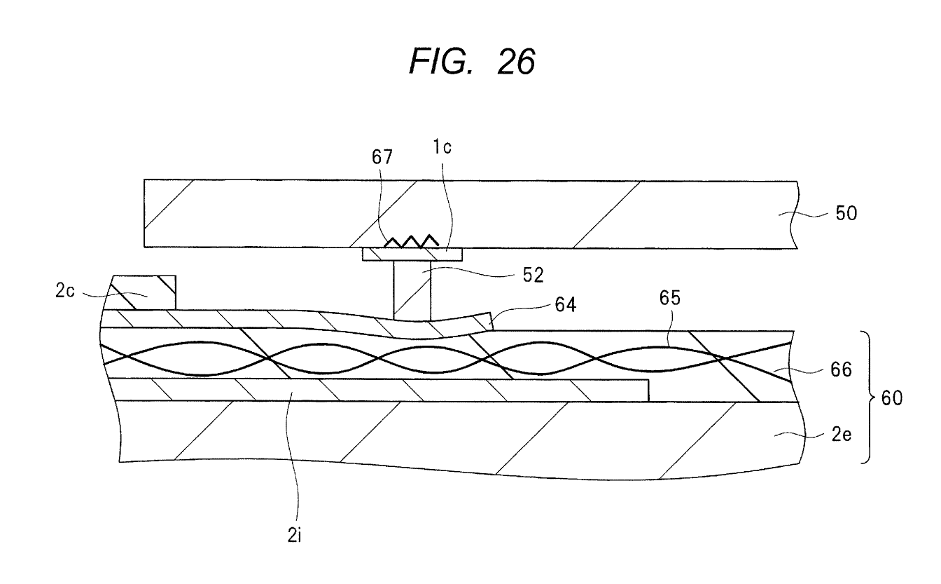

In addition, the bonding lead 2m of the wiring board 2 connected with, among the copper pillars 4, a copper pillar having a height greater than that of the other copper pillars 4 sinks so that formation of a crack 67 (refer to FIG. 26) in an insulation layer immediately below the pad 1c of the semiconductor chip 1 on which this high copper pillar 4 is formed can be suppressed. This makes it possible to improve the reliability of the BGA 7.

Further, even when a stress is applied to the solder balls 5 or the like of the BGA 7, this stress can be relaxed with the soft resin layer 2db and direct propagation of the damage to the flip chip connection can be suppressed.

Described specifically, since the soft resin layer 2db is arranged below the bonding leads 2m with which the copper pillar 4 is connected, even a stress including a thermal stress applied to the solder balls 5 is absorbed by the deformation of the soft resin layer 2db to relax the stress and prevent direct propagation of the damage to the flip chip connection or semiconductor chip 1.

As a result, occurrence of a connection failure at the flip chip connection can be suppressed.

### <Wiring Board>

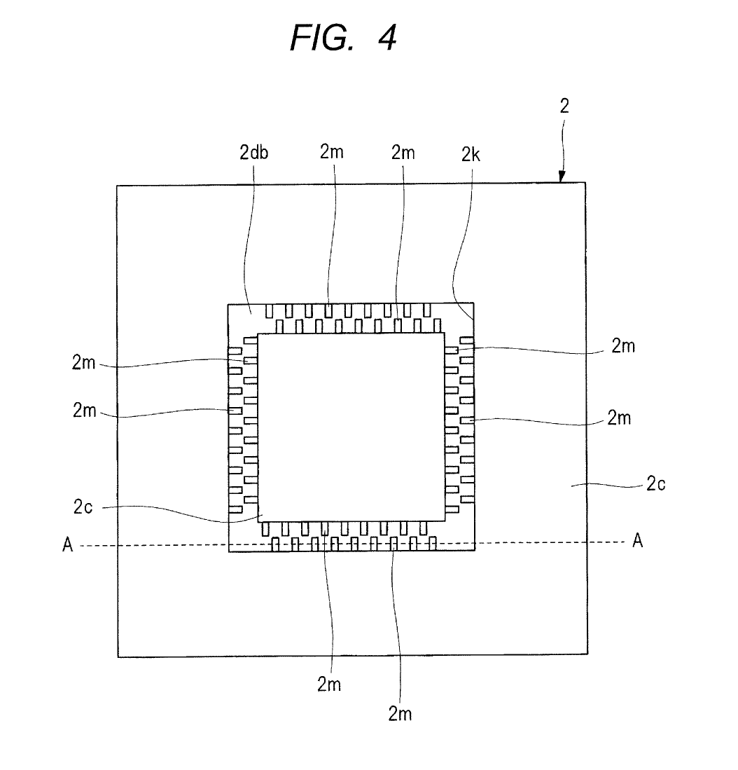

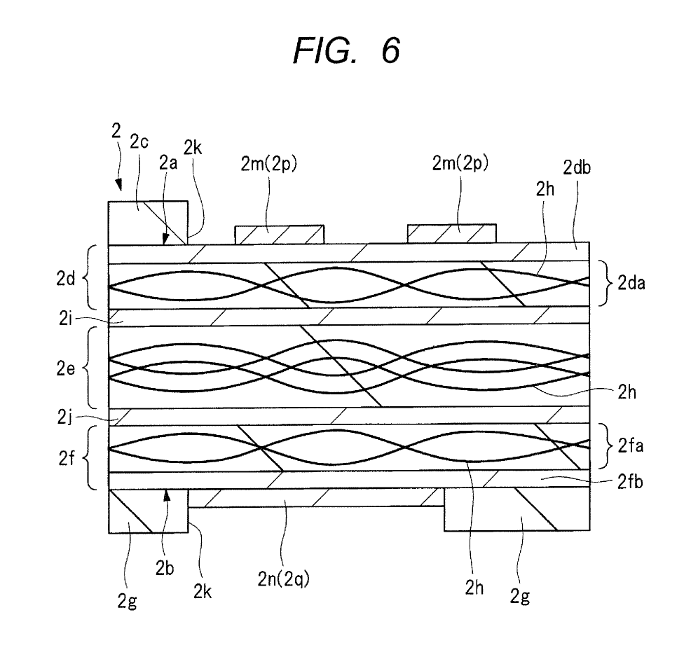

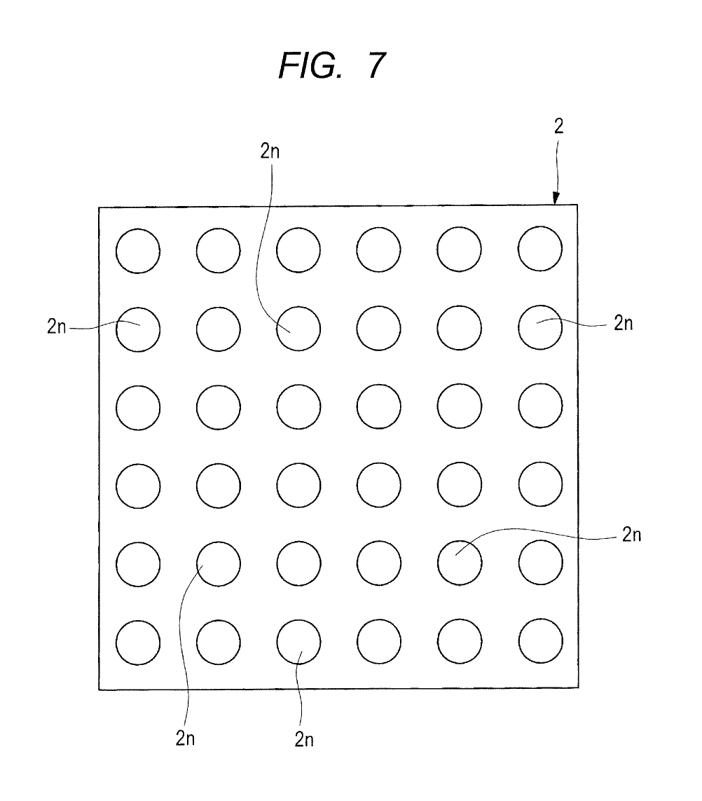

FIG. 4 is a plan view showing one example of the upper surface side structure of a wiring board to be incorporated in the semiconductor device shown in FIG. 1; FIG. 5 is a cross-sectional view showing one example of the structure taken along a line A-A shown in FIG. 4; FIG. 6 is an enlarged fragmentary cross-sectional view showing one example of the structure of portion B shown in FIG. 5; and FIG. 7 is a back surface view showing one example of the lower surface side structure of the wiring board shown in FIG. 4.

A detailed structure of the wiring board 2 according to the present embodiment will next be described.

The wiring board 2 is, as described above, a multilayer wiring board and in the present embodiment, a multilayer wiring board having four wiring layers will be described as an example. The number of the wiring layers is however not limited to four.

The wiring board 2 has an upper surface 2a having a square planar shape as shown in FIG. 4 and a lower surface 2b which is a mount surface or a back surface opposite to the upper surface 2

As shown in FIG. 4, the wiring board 2 has, on the upper surface 2a thereof, a plurality of bonding areas 2m for flip chip connection formed on the uppermost wiring layer. They are arranged in two rows, an inside row and an outside row, in an opening portion 2k of a solder resist film 2c shown in FIG. 5. The bonding leads of the inside row and the outside row are arranged without overlapping with each other so that they correspond to pads arranged on the side of the chip in a zigzag manner and are suited for multi-pin connection.

From the opening portion 2k of the solder resist film 2c having the bonding leads 2m therein, a resin layer 2db that supports these bonding leads 2m is also exposed.

As shown in FIG. 7, on the other hand, on the lower surface 2b of the wiring board 2, a plurality of lands 2n for solder ball connection formed in the lowermost wiring layer is arranged in a plurality of opening portions 2k of a solder resist film 2g shown in FIG. 5, respectively, and these lands 2n are arranged in lattice form.

As shown in FIGS. 5 and 6, the wiring board 2 is formed by laminating a core layer (prepreg) 2e, wiring layers 2i and 2j respectively arranged on the upper surface and the lower surface of the core layer 2e, insulation layers (insulating films) 2d and 2f, and wiring layers 2p and 2q which are the uppermost layer and the lowermost layer, respectively. These members are laminated with each other by contact bonding by pressing. For example, members such as the core layer 2e, the wiring layers 2i and 2j, the insulation layers 2d and 2f, and the wiring layers 2p and 2q are sandwiched between flat plate-like steel plates and pressed at high temperature under high pressure.

Therefore, depending on the position of a device region 2u (refer to FIG. 12), there occur variations in height, particularly among wirings (including electrodes such as the bonding leads 2m and the lands 2n) formed on the outermost layers such as uppermost layer and the lowermost layer.

The wiring board 2 according to the present embodiment has a structure having four wiring layers as shown in FIG. 6. It has, on the surface and the back surface of the core layer 2e thereof, the wiring layer 2i and the wiring layer 2j, respectively and has a plurality of wirings (wiring patterns) in the uppermost wiring layer 2p and the lowermost wiring layer 2q via the insulation layer 2d and the insulation layer 2f. A portion of each of the wirings formed in the uppermost wiring layer 2p constitutes the plurality of bonding leads (electrodes) 2m for flip chip connection.

Due to the above-mentioned manufacturing method (contact bonding) of the wiring board, therefore, variations in height tend to occur among the bonding leads 2m which are electrodes formed in the uppermost (outermost) wiring layer 2p.

The wiring board 2 has, in the lowermost wiring layer (on the side of the lower surface 2b) 2q, thereof, a plurality of lands 2n for connecting solder balls 5 therewith. This means that a portion of each of the wirings formed in the lowermost wiring layer 2q constitutes a plurality of lands (electrodes) 2n for connecting therewith the solder balls which are outer terminals.

In the wiring board 2, the plurality of bonding leads 2m is formed on the side of the upper surface 2a and the plurality of lands 2n corresponding to the plurality of bonding leads 2m is formed on the side of the lower surface 2b. The bonding leads 2m and the lands 2n corresponding to each other are electrically connected with each other via inner wirings, through-hole wirings, or the like which are not illustrated.

The wiring board 2 has, on the upper surface 2a and the lower surface 2b thereof, solder resist films 2c and 2g which are insulating films, respectively. On the side of the upper surface 2a, the solder resist film 2c has, in the opening portion 2k thereof, the plurality of bonding leads 2m, while on the side of the lower surface 2b, the solder resist film 2g has, in the plurality of opening portions 2k thereof, the lands 2n, respectively.

This means that on the side of the upper surface 2a of the wiring board 2, the insulation layer 2d has, on the upper surface thereof, the solder resist film (upper surface side protective film) 2c so as to expose the plurality of bonding leads 2m, while on the side of the lower surface 2b of the wiring board 2, the insulation layer 2f has, on the lower surface thereof, the solder resist film (lower surface-side protective film) 2g so as to expose the plurality of lands 2n.

On the side of the upper surface 2a, the insulation layer 2d has thereon the plurality of bonding leads 2m. This insulation layer 2d is comprised of a prepreg (resin layer) 2da having a glass cloth (glass fibers) 2h and a resin layer 2db not having a glass cloth 2h and this prepreg 2da has thereon the resin layer 2db.

These bonding leads 2m are therefore each in contact with the resin layer 2db and they are arranged on this resin layer 2db. In other words, these bonding leads 2m are supported by the resin layer 2db.

Also on the side of the lower surface 2b, the insulation layer 2f has thereon the plurality of lands 2n. This insulation layer 2f is comprised of a prepreg (resin layer) 2fa having a glass cloth (glass fibers) 2h and a resin layer 2fb not having a glass cloth 2h. Similar to the side of the upper surface 2a, the each of lands 2n contacts with the resin layer 2fb and they are arranged on this resin layer 2fb. In other words, these lands 2n are supported by the resin layer 2fb.

The above-mentioned resin layers (resin materials) 2db and 2fb are made of, for example, an epoxy resin. The resin of the resin layers 2db and 2fb is a resin not having a glass cloth (glass fibers) 2h, though having a plurality of fillers.

On the other hand, the prepregs 2da and 2fa are made of, for example, an epoxy resin. The resin of the prepregs 2da and 2fa has a plurality of fillers and further has a glass cloth (glass fibers) 2h.

When the prepregs 2da and 2fa having a glass cloth 2h and the resin layers 2db and 2fb not having a glass cloth 2h are compared, the prepregs 2da and 2fa have greater (higher) hardness and greater rigidity. In other words, the prepregs 2da and 2ft having a glass cloth 2h are hard, but the resin layers 2db and 2fb not having a glass cloth 2h have small (low) hardness and are soft.

The bonding leads 2m are each arranged directly on the soft resin layer 2db and this soft resin layer 2db has therebelow the hard prepreg 2da.

On the other hand, the lands 2n on the side of the lower surface 2b are each arranged directly on the soft resin layer 2fb and this soft resin layer 2fb has therebelow (on the side of the core layer 2e, on the side of the lower surface 2b) the hard prepreg 2fa.

The bonding leads 2m, the lands 2n, and wirings of the wiring layers in the wiring board 2 are each made of a material composed mainly of copper and the bonding leads 2m and the lands 2n have a plated surface.

With regards to the thickness of each of the layers of the wiring board 2, the prepregs 2da and 2fa which are resin layers have a thickness of, for example, 30 μm and the resin layers 2db and 2fb on the prepreg 2da and 2fa have a thickness of, for example, 5 μm. The core layer 2e has a thickness of, for example, from 40 to 60 μm and the wiring layers each has a thickness of, for example, ten and several μm. This means that the resin layers 2db and 2fb are thinner than the prepregs 2da and 2fa.

The thickness of the resin layer 2db may be equal to that of the prepreg 2da or may be greater than that of the prepreg 2da.

It is however preferred to make the resin layer 2db or 2fb thinner than the prepreg 2da or 2fa as in the present embodiment when the warpage of the wiring board or thinning of the semiconductor device is taken into consideration.

The bonding leads 2m of the wiring board 2 may have, on the surface thereof, a solder material 3. The solder material 3 arranged on each of the copper pillars 4 and each of the bonding leads 2m can absorb variations in height of the members when a load is applied during flip chip connection.

When the solder material 3 is not arranged on each of the bonding leads 2m (the bonding leads 2m made of solid copper or the bonding leads 2m having a gold-plated surface), the cost of the BGA 7 can be reduced because the solder material 3 is not used.

### <Semiconductor Chip>

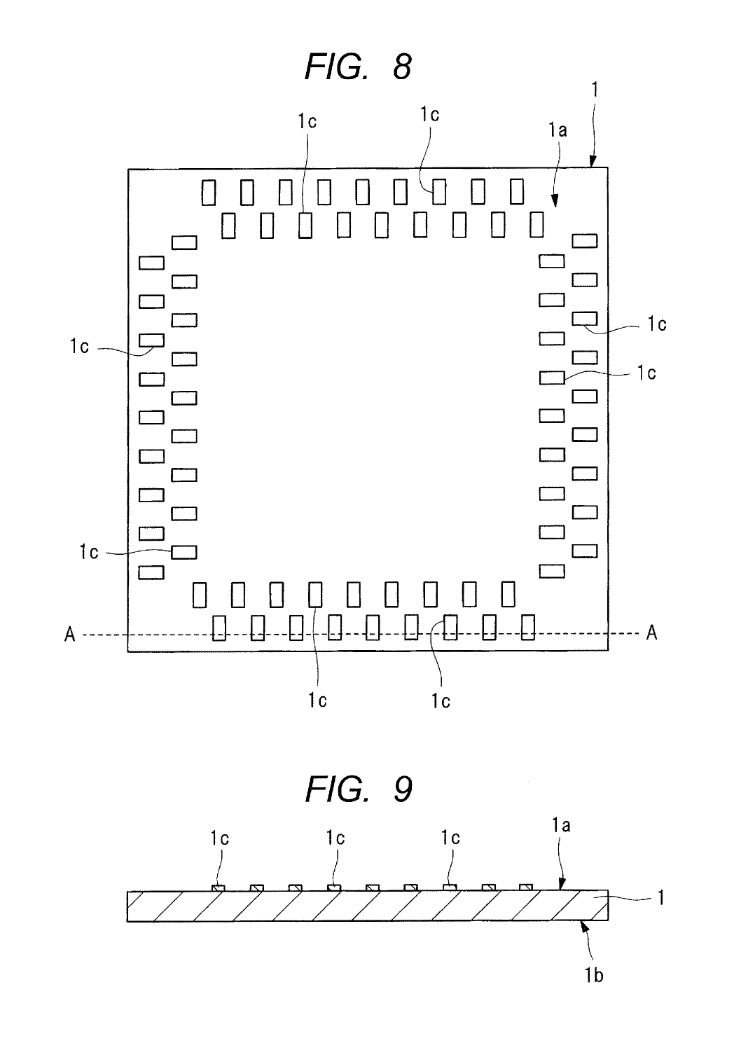

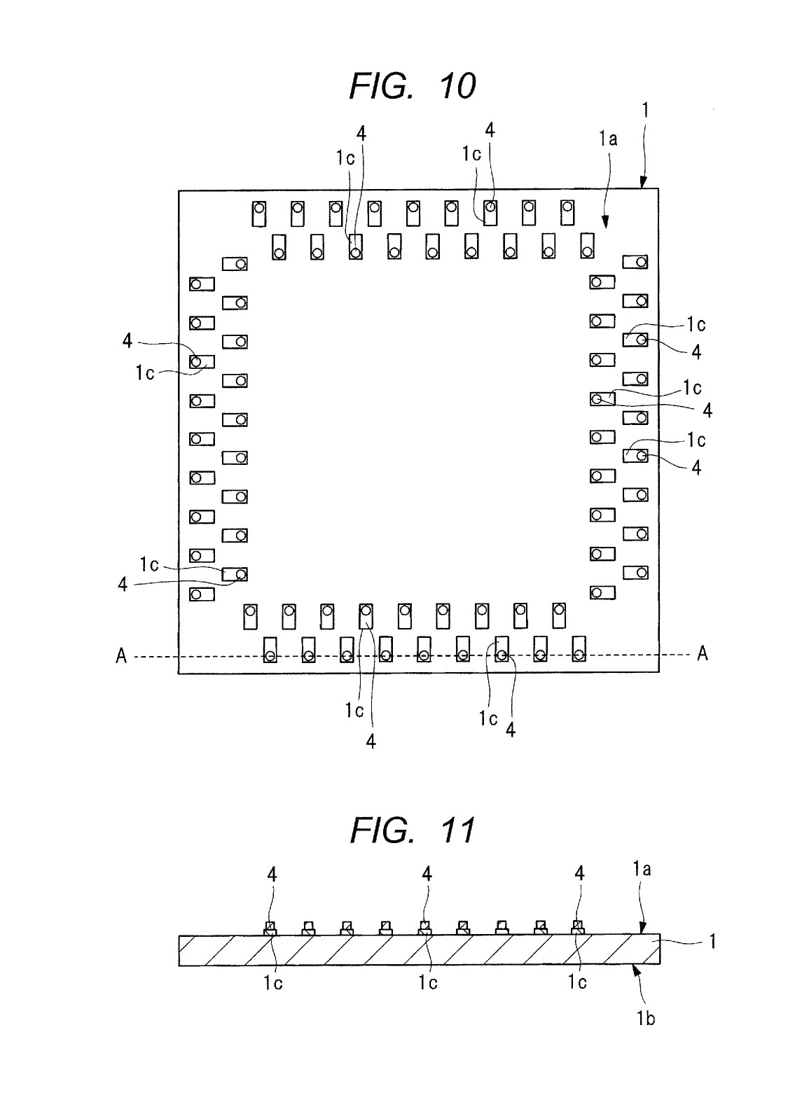

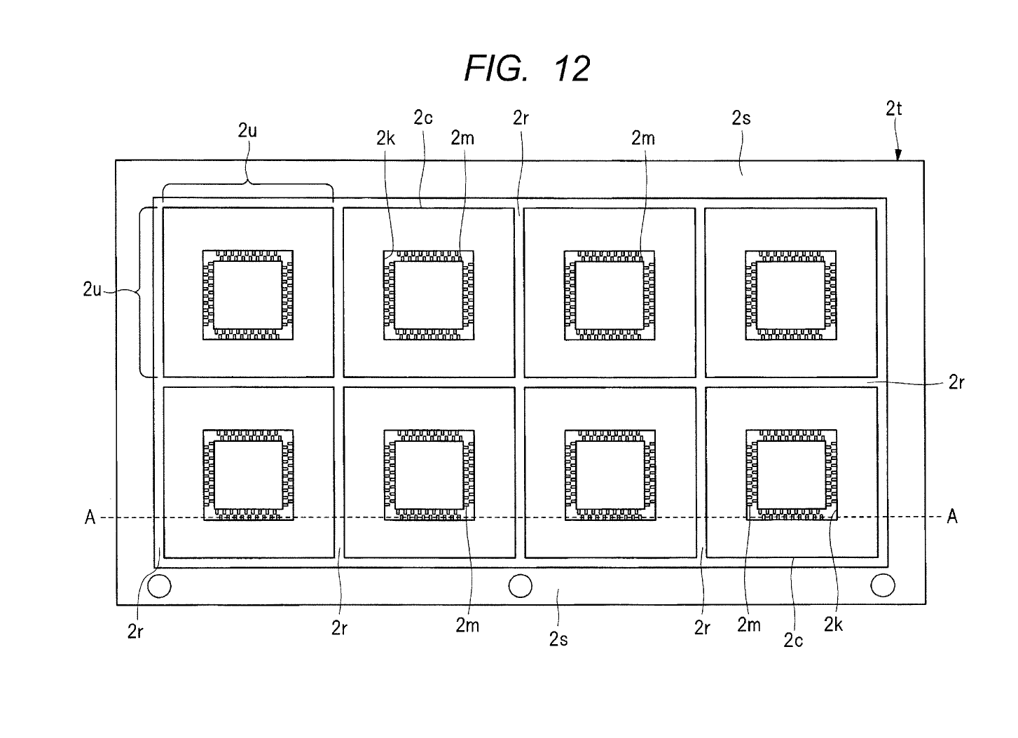

FIG. 8 is a plan view showing one example of the main surface side structure of a semiconductor chip to be mounted on the semiconductor device shown in FIG. 1; FIG. 9 is a cross-sectional view showing one example of the structure taken along a line A-A shown in FIG. 8; FIG. 10 is a back surface view showing one example of the back surface side structure of the semiconductor chip to be mounted on the semiconductor device shown in FIG. 1; and FIG. 11 is a cross-sectional view showing one example of the structure taken along a line A-A of FIG. 10.

As shown in FIGS. 8 and 9, the semiconductor chip has, on the main surface 1a thereof, a plurality of pads 1c in two rows at the periphery (outer circumferential portion) of the main surface 1a. The semiconductor chip 1 according to the present embodiment is suited for multi-pin connection so that these pads 1c are provided in a zigzag manner.

Further, as shown in FIGS. 10 and 11, the copper pillar 4, which are conductive members, are connected with the pads 1c, respectively. The copper pillars 4 are each a columnar (post-like) electrode and made of, for example, a material having copper (Cu) as a main component.

The copper pillar 4 is formed, for example, by electroplating. Described specifically, this pillar is formed by placing, on the main surface (element formation surface) of an unillustrated semiconductor wafer, a dry film having a plurality of round holes corresponding to the pad arrangement in each of chip formation regions of the semiconductor wafer and stacking in the holes from below by electroplating.

As the conductive member, a protruding (bump) electrode may be used. The protruding electrode is made of, for example, a material having gold (Au) as a main component. The protruding electrode is formed using a wire bonding technology with a capillary so that a semiconductor wafer is cut into semiconductor chips prior to the formation of this protruding electrode.

The columnar electrode is obtained by, as described above, forming a dry film (resist film) on the main surface of a semiconductor wafer and then forming a plurality of pads of each of the chip formation regions, for example, by electroplating (electroless plating can also be used). From the standpoint of the number of steps for forming the conductive member, using a columnar (post-like) electrode is preferred as in the present embodiment.

### <Manufacturing Method of Semiconductor Device>

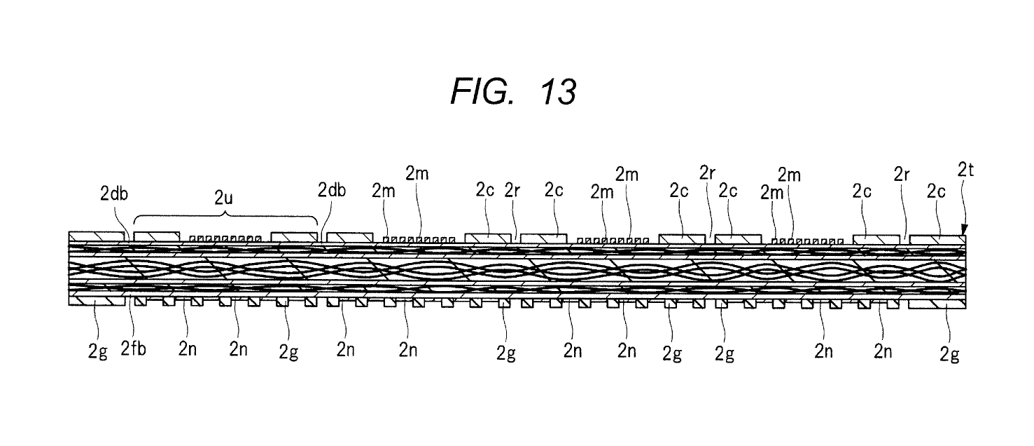

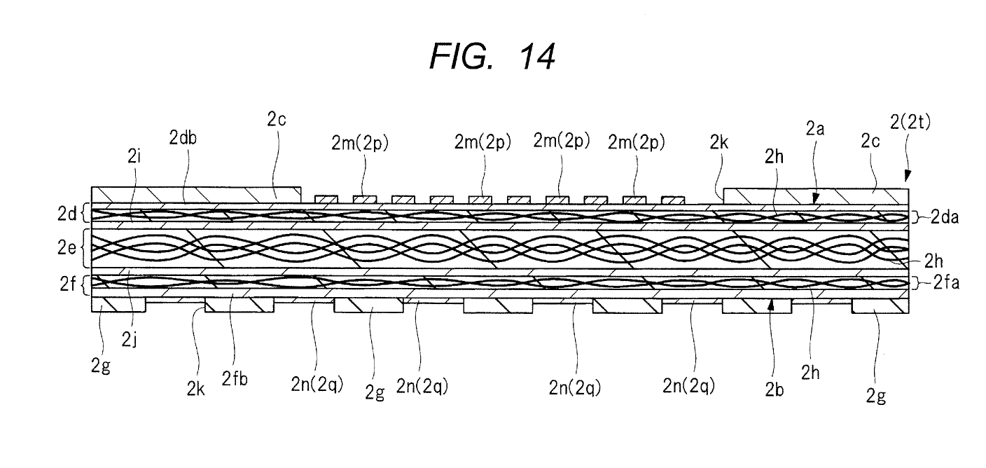

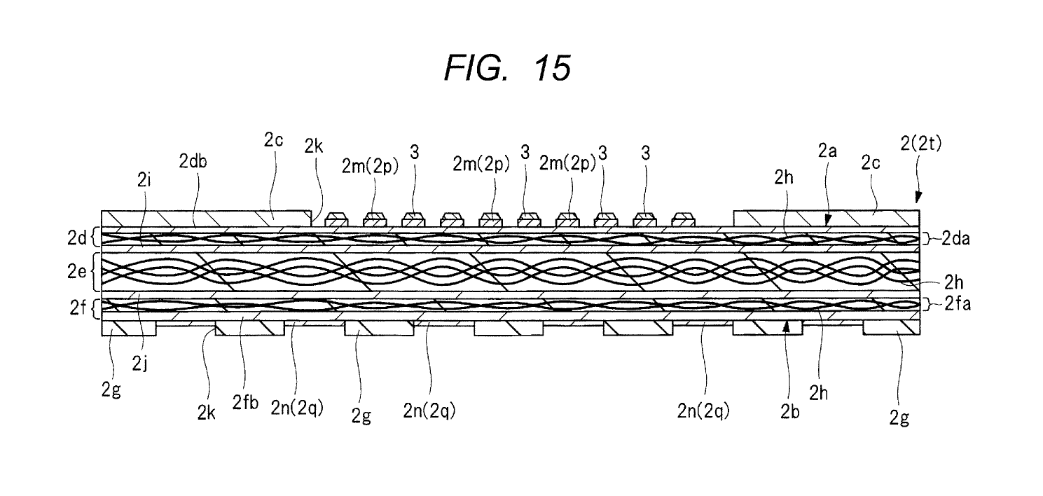

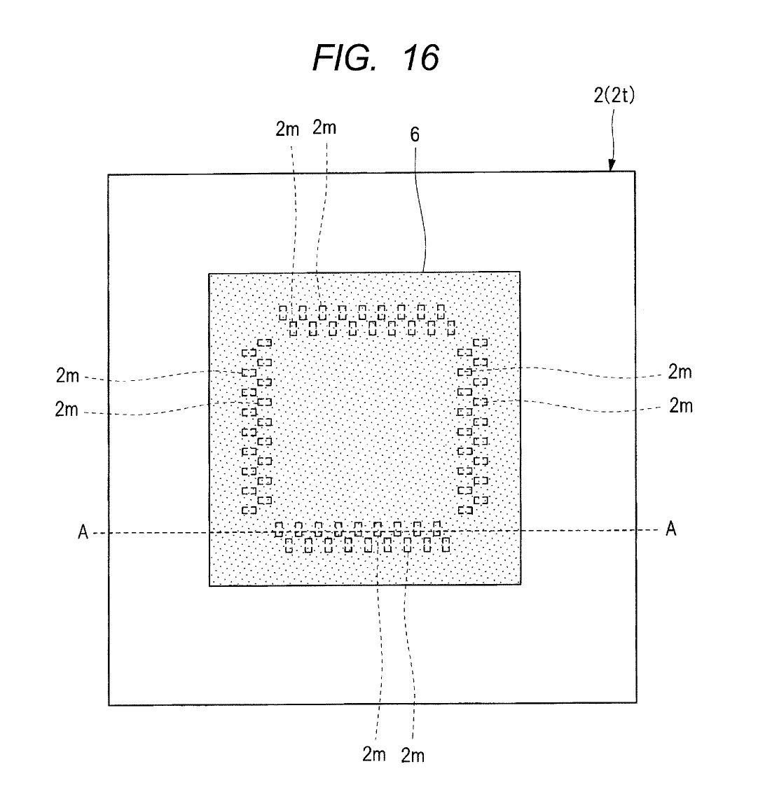

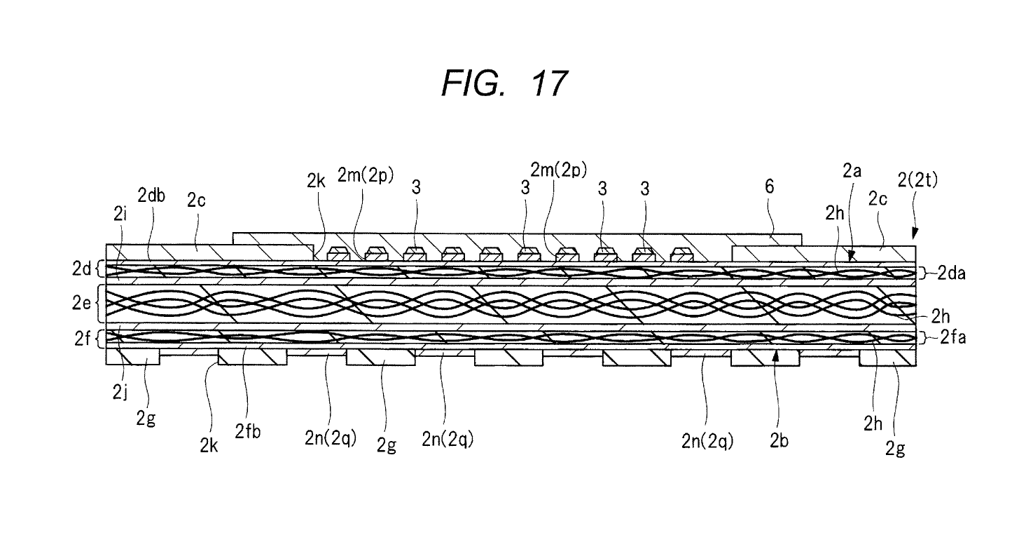

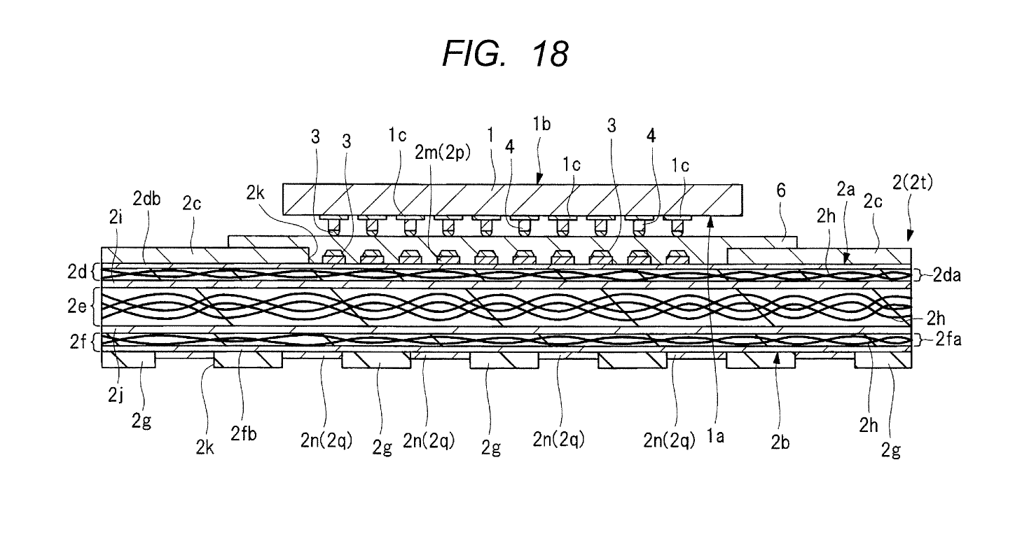

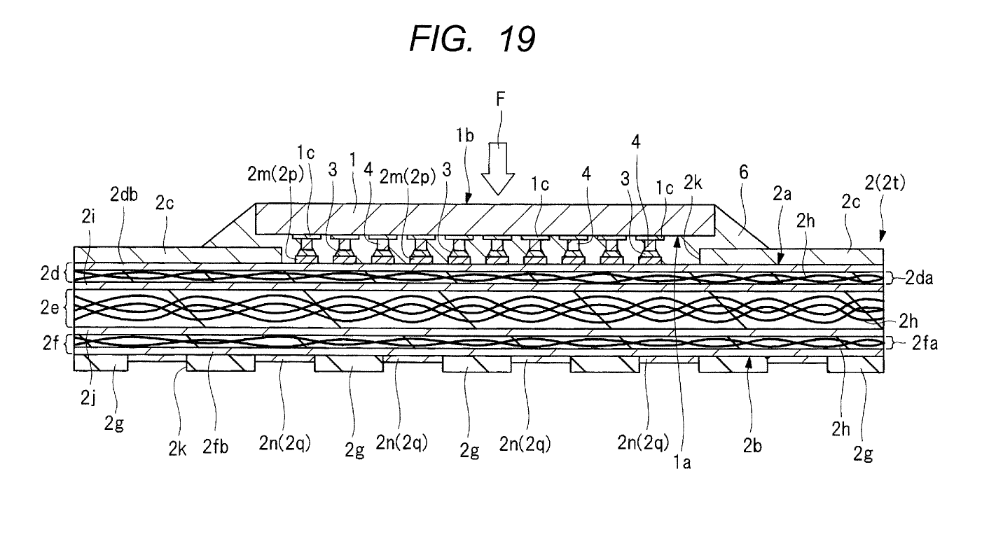

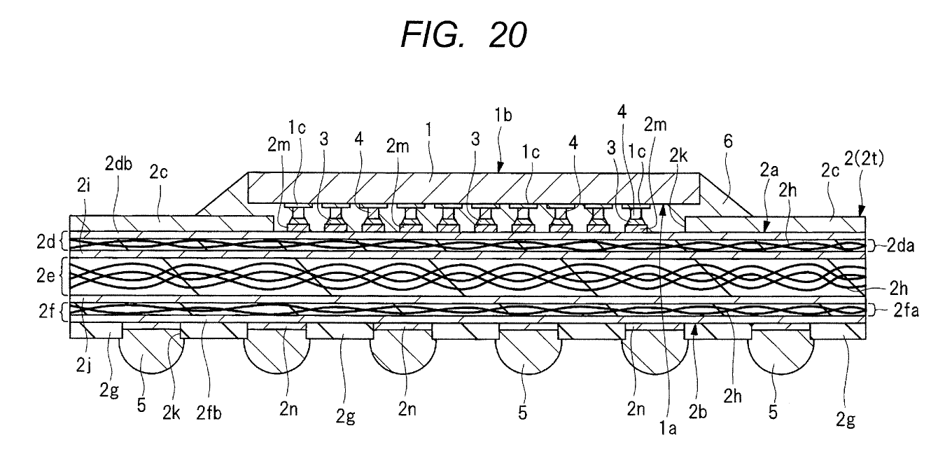

FIG. 12 is a plan view showing one example of the structure of a wiring board to be used in the fabrication of the semiconductor device shown in FIG. 1; FIG. 13 is a cross-sectional view showing one example of the structure taken along a line A-A of FIG. 12; FIG. 14 is a cross-sectional view showing one example of the structure of one device region in the wiring board shown in FIG. 12; and FIG. 15 is a cross-sectional view showing one example of the structure after solder precoating in the fabrication of the semiconductor device shown in FIG. 1. FIG. 16 is a plan view showing one example of the structure after underfill application in the fabrication of the semiconductor device shown in FIG. 1; FIG. 17 is a cross-sectional view showing one example of the structure taken along a line A-A in FIG. 16; and FIG. 18 is a cross-sectional view showing one example of the structure after chip mounting in a flip chip bonding step in the fabrication of the semiconductor device shown in FIG. 1. FIG. 19 is a cross-sectional view showing one example of the structure after pressure bonding of the chip in the flip chip bonding step shown in FIG. 18; and FIG. 20 is a cross-sectional view showing one example of the structure after ball mounting in the fabrication of the semiconductor device shown in FIG. 1.

### 1. Provision of Wiring Board (Multi-Piece Wiring Board)

The wiring board according to the present embodiment is, as shown in FIGS. 12 and 13, a multi-piece wiring board (matrix board) 2t having a plurality of device regions 2u. Fabrication of a semiconductor device by using this multi-piece wiring board 2t will hereinafter be described. A semiconductor device may however be fabricated by using a wiring board which has been divided into each device region 2u in advance.

In the fabrication of the semiconductor device according to the present embodiment, a description will be made referring to drawings showing only one of the device regions 2u for convenience sake. It is needless to say that when the device is manufactured using the multi-piece wiring board 2t, a plurality of the device regions 2u on the multi-piece wiring board 2t is subjected to a desired treatment in each step.

First, a multi-piece wiring board 2t is provided. The multi-piece wiring board 2t has an upper surface 2a and a lower surface 2b on the side opposite to the upper surface 2a. Further, the multi-piece wiring board 2t is equipped with a plurality of device regions 2u (2×4=8 device regions 2u shown here as one example), a cutting site 2r provided between the device regions 2u adjacent to each other among the plurality of device regions 2u, and a frame portion 2s provided around the plurality of device regions 2u in a plan view. The cutting site 2r is also called “removal site”, “dicing site”, “dicing region”, or the like.

The cutting site 2r is in a groove form as shown in FIG. 13. More specifically, the cutting site is a groove formed by etching and thereby removing an electric supply line for forming a plating film on the surface of each wiring by an electroplating method after forming the plating film. Since the cutting site 2r is in a groove form, generation of cutting dusts from the solder resist film 2c during dicing in a singulation step can be reduced. Further, a load to a dicing blade can also be reduced. Thus, cutting can be performed with an improved technology.

At the extension of each of the cutting sites 2r on the frame portion 2s shown in FIG. 12, there is an unillustrated dicing mark. During dicing for singulation, after recognition of the mark, a running line of the blade is found therefrom and then, the blade which is rotating is caused to run to cut the board at the cutting site 2r.

As shown in FIG. 12, in each of the device regions 2u, in the opening portion 2k of the solder resist film 2c near the center portion of the device region, bonding leads 2m for flip chip connection are arranged along each side of the multi-piece wiring board 2t in two or more rows (here, two rows). Depending on the arrangement of the pads 1c of the semiconductor chip 1 shown in FIG. 8, two rows of the bonding leads 2m are arranged in a zigzag manner. The number of the rows of the bonding leads 2m may be single (one row).

In each of the device regions 2u of the multi-piece wiring board 2t according to the present embodiment, the bonding leads 2m are arranged on an insulation layer 2d as shown in FIG. 14. This insulation layer 2d is comprised of a prepreg (resin layer) 2da having a glass cloth (glass fibers) 2h and a resin layer 2db not having the glass cloth 2h. The prepreg 2da has thereon the resin layer 2db.

Due to such a structure, each of the bonding leads 2m is in contact with the resin layer 2db and is arranged on this resin layer 2db. In other words, the bonding leads 2m are supported by the resin layer 2db having lower hardness and softer than the prepreg 2da.

The multi-piece wiring board 2t has, on the lower surface 2b thereof, a plurality of lands 2n electrically connected with the bonding leads 2m on the upper surface 2a and has, on the lower surface 2b, a solder resist film 2g so as to expose each of the lands 2n.

The multi-piece wiring board 2t is obtained by overlapping a core layer (prepreg) 2e, wiring layers 2i and 2j on and under the core layer 2e, insulation layers (insulating films) 2d and 2f, a wiring layer 2p constituting the bonding leads 2m, and a wiring layer 2q constituting the lands 2n one after another and bonded by pressing. For example, members such as the core layer 2e, the wiring layers 2i and 2j, the insulation layers 2d and 2f, and the wiring layers 2p and 2q are sandwiched between flat plate-like steel plates, followed by pressing them at a high temperature under a high pressure.

Depending on the position in the device region 2u, variations tend to occur in the height of electrodes, particularly, electrodes such as the bonding leads 2m of the uppermost wiring layer 2p or electrodes such as the lands 2n of the lowermost wiring layer 2q.

For example, in the bonding leads 2m formed in the uppermost (outermost) wiring layer 2p, variations in electrode height may occur due to contact bonding by pressing.

In consideration of a reduction in connection failures in flip chip connection due to the above-mentioned variations in the electrode height, solder materials 3 are preferably arranged on the surface of each of the bonding leads 2m as shown in FIG. 15. This means that at the time of flip chip connection, above-mentioned variations in electrode height can be absorbed by the solder materials 3 arranged respectively on the surfaces of the bonding leads 2m, which leads to a reduction in connection failures in the flip chip connection.

When the copper pillar 4 is used as a conductive member for flip chip connection as shown in the semiconductor chip 1 of FIG. 10, however, the solder material 3 on the surface of each of the bonding leads 2m is not always necessary. In this case, omission of this solder material 3 leads to a reduction in the cost of the wiring board.

### 2. Arrangement of Molding Material (Application of Underfill)

As shown in FIGS. 16 and 17, an underfill (molding material) 6 is arranged on the upper surface 2a of the wiring board 2. This underfill 6 is arranged so as to cover a plurality of bonding leads 2m therewith. The underfill 6 is, for example, an NCF (non-conductive film) and a molding material (adhesive) in film form made of an insulative epoxy resin or the like. Alternatively, an NCP (non-conductive paste) which is a molding material in paste form may be used.

Here, the underfill 6 is arranged on the wiring board 2 prior to flip chip connection. Alternatively, the underfill 6 may be filled between the wiring board 2 and the semiconductor chip 1 after flip, chip connection.

### 3. Flip Chip Bonding

As shown in FIG. 18, the semiconductor chip 1 is arranged on the upper surface 2a of the wiring board 2. It is arranged while matching the position of the pads 1c of the semiconductor chip 1 shown in FIG. 10 to the position of the bonding leads 2m of the wiring board 2. The semiconductor chip 1 has, as shown in FIGS. 10 and 11, columnar (or protruding) conductive members (a plurality of copper pillars 4 in the present embodiment) formed on each of the pads 1c.

As shown in FIG. 18, the copper pillars 4 have, on the end surface (surface facing to the bonding leads 2m) thereof, solder materials 3, respectively.

The semiconductor chip 1 having the pads 1c provided with the copper pillars 4 having the solder material 3 on the end surfaces thereof is arranged on the upper surface 2a of the wiring board 2 via the copper pillars 4 so that the main surface 1a of the semiconductor chip 1 faces to the upper surface 2a of the wiring board 2.

Then, as shown in FIG. 19, pressure bonding of the chip is conducted. At this time, the solder material 3 formed on the end surface of the copper pillar 4 is brought into contact with the bonding lead 2m of the wiring board 2 by applying, to the back surface 1b of the semiconductor chip 1, heat and a load (vertical load) F in the thickness direction (perpendicular direction, direction from the upper surface 2a to the lower surface 2b of the wiring board 2) of the wiring board 2. Heat is then applied to a portion to be connected (bonded) between the copper pillar 4 and the bonding lead 2m to melt the solder material 3 and electrically connect the copper pillars 4 and the bonding leads 2m with each other via the solder material 3.

In the wiring board 2 of the present embodiment, the insulation layer 2d that supports the bonding leads 2m is the soft resin layer 2db not containing the glass cloth 2h. When a load is applied to the bonding leads 2m during flip chip bonding, the resin layer 2db therefore deforms and the bonding leads 2m provided on this resin layer 2db sink. Variations in height among the bonding leads 2m or the conductive members (copper pillars 4), if any, therefore does not prevent connection between the copper pillars 4 having a small height and the bonding leads 2m. Further, since the bonding leads 2m have, in the lower portion (on the side of the core layer 2e, on the side of the lower surface 2b) thereof, the soft resin layer 2db so that even when a load is applied to the bonding leads 2m from the copper pillars 4 during flip chip bonding, a stress attributable to variations in height of the electrodes can be absorbed by sinking of the soft resin layer 2db. As a result, a stress to be applied to the semiconductor chip 1 can be reduced.

This makes it possible to reduce damage to the semiconductor chip 1 and thereby prevent cracks in the semiconductor chip 1 or inconveniences such as exfoliation of a surface protective film. In short, damage to the semiconductor chip 1 during flip chip bonding can be reduced or prevented.

As a result, reliability of the semiconductor device (BGA 7) can be improved.

When a load is applied during flip chip bonding, the resin layer 2db that supports the bonding leads 2m sinks to absorb variations in height among the copper pillars 4 or the bonding leads 2m. This makes it possible to reduce connection failures of the semiconductor chip 1 at the time of flip chip bonding and thereby improve the connection reliability of the semiconductor chip 1.

As a result, reliability of the semiconductor device (BGA 7) can be improved.

In the wiring board 2, the prepreg 2da has hardness greater than that of the resin layer 2db by making the thickness of the prepreg 2da greater than that of the resin layer 2db. As a result, the warpage of the board can be reduced. Further, the thickness of the core layer 2e can be decreased by thickening the prepreg 2da of the insulation layer 2d. This leads to a decrease in the total thickness of the wiring board 2 and moreover, a decrease in thickness of the semiconductor device (BGA 7).

The copper pillars 4 each has, on the end surface thereof, the solder material 3. The solder material 3 melt by heating and absorbs a space between the copper pillar 4 and the bonding lead 2m formed due to variations in height among the copper pillars 4 or the bonding leads 2m when the copper pillars 4 are arranged by force.

When not only the copper pillars 4 but also the bonding leads 2m have on the surfaces thereof the solder materials 3, variations in height among the copper pillars 4 or the bonding leads 2m can be absorbed further and connection failures of the semiconductor chip 1 at the time of flip chip bonding can be reduced further.

In addition, by using the copper pillars 4 as a conductive member, the copper pillars 4 can be connected with the pads 1c collectively in a wafer stage. Thus, the conductive member can be connected efficiently with the pads 1c.

The copper pillars 4 are columnar conductive members such that they can secure an electrode height (distance between the semiconductor chip 1 and the wiring board 2) in flip chip bonding.

When a load F is added, the underfill 6 is also flattened downwardly by the semiconductor chip 1 so that the flip chip connection is filled with the underfill 6 and the underfill 6 flattened to protrude from the periphery of the semiconductor chip 1 extends over each of the side surfaces of the semiconductor chip 1. As a result, the side surfaces of the semiconductor chip 1 are each covered with the underfill 6.

Flip chip bonding is completed by the above-mentioned steps.

### 4. Formation of External Terminal (Ball Mounting)

In an external terminal formation step, as shown in FIG. 20, a plurality of solder balls 5 is formed on or connected with the plurality of lands 2n on the lower surface 2b of the wiring board 2. These solder balls 5 are also called external terminals, ball-like electrodes, or the like.

The external terminal to be connected with the lands 2n is not limited to a ball-like solder material and it may be obtained by coating the surface of the lands 2n with a solder material or a plating film (plating layer) formed on the surface of the lands 2n. In this case, the semiconductor device thus obtained is a LGA (land grid array).

The solder material used for the solder balls 5 is, similar to the above-mentioned solder material 3, made of a so-called lead-free solder containing substantially no lead (Pb). For example, it is made only of tin (Sn) or made of tin-copper-silver (Sn—Cu—Ag).

### 5. Singulation

A Singulation step is conducted using a dicing blade (not illustrated) which is a rotating cutting blade. For example, singulation into each BGA 7 is conducted by inserting the blade into the cutting site 2r from above the multi-piece wiring board 2t as shown in FIG. 12, rotating it, and thereby dicing the wiring board.

The singulation may be achieved not only by dicing with the blade but also by cutting with a die.

In the above-mentioned manner, fabrication of the BGA 7 shown in FIGS. 1 to 3 is completed.

### MODIFICATION EXAMPLES

The invention made by the present inventors has been described specifically based on the embodiment of the invention. It is however needless to say that the invention is not limited to the above-mentioned embodiment of the invention but can be changed in various ways without departing from the scope of the invention.

### Modification Example 1

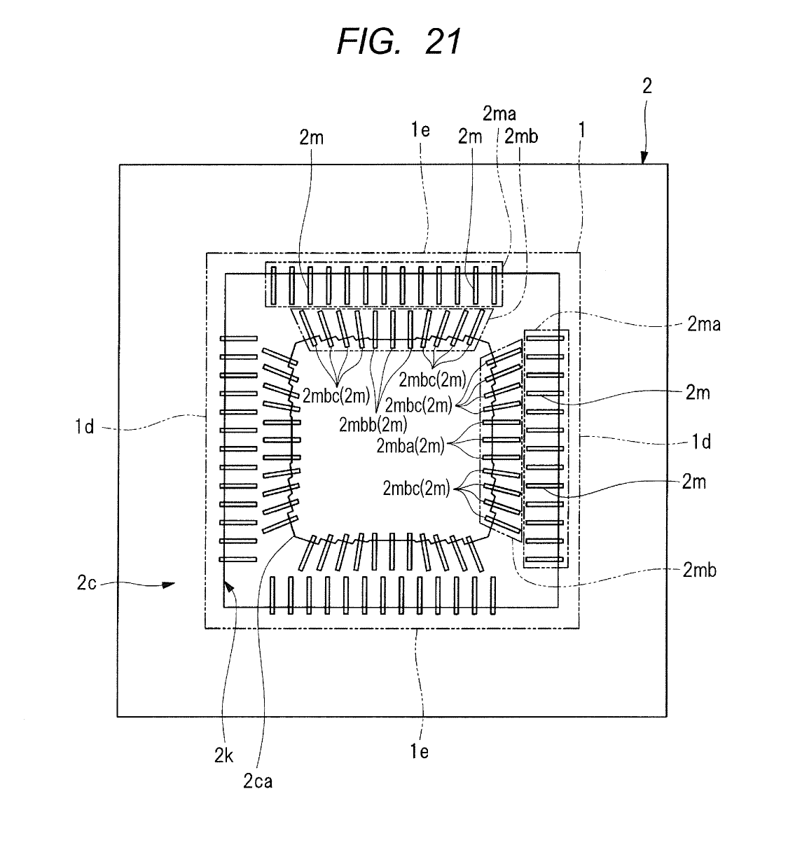

FIG. 21 is a plan view showing one example of lead arrangement on the upper surface side of a wiring board to be incorporated in a semiconductor device according to Modification Example 1 of the embodiment.

The structure shown in FIG. 21 shows a modification example of a flip chip bonding type semiconductor device employing multi-pin connection in which the arrangement mode of a plurality of bonding leads 2m on a wiring board 2 has been modified.

In the semiconductor device employing multi-pin connection, as is apparent from the semiconductor chip 1 shown in FIG. 8, pads 1c are often arranged in a zigzag manner. A plurality of bonding leads 2m provided in an opening portion 2k of a solder resist film 2c on the side of a wiring board shown in FIG. 21 is arranged in two rows, that is, an outer peripheral lead group 2ma and an inner peripheral lead group 2mb.

Further, in the wiring board 2, the inner peripheral lead group 2mb has, in a plan view, a plurality of bonding leads 2mba extending in a direction crossing with (almost perpendicular to) a side 1d of the semiconductor chip 1, a plurality of bonding leads 2mbb extending in a direction crossing with (almost perpendicular to) a side 1e of the semiconductor chip 1, and a plurality of bonding leads 2mbc extending in a direction perpendicular to neither the side 1d nor the side 1e.

This means that the bonding leads 2m of the inner peripheral lead group 2mb exposed from the frame-like opening portion 2k of the solder resist film 2c can be classified into the above-mentioned three groups (bonding leads 2mba, 2mbb, and 2mbc), depending on their extending direction. Of these bonding leads of three groups, the bonding leads 2mbc extending in a direction perpendicular to neither the side 1d nor the side 1e of the semiconductor chip 1 are arranged in the vicinity of the corner of the frame-like opening portion 2k.

This means that among the bonding leads 2m of the inner periphery lead group 2mb, the bonding lead 2mbc arranged in the vicinity of the corner of the opening portion 2k is likely to contact with a bonding lead 2mbc located at the end portion (corner) of another lead row almost perpendicular to the lead row including the above-mentioned bonding lead 2mbc. The bonding lead arranged in the vicinity of the corner is therefore arranged obliquely to the bonding leads 2m in the vicinity of the center portion of the arrangement. When only the bonding lead 2mbc at the end position is arranged obliquely, interference between this bonding lead 2mbc and a bonding lead 2mbc in the same row but adjacent thereto occurs at their inner end portions. A plurality (four leads counted from the end in FIG. 21) of bonding leads 2mbc in the vicinity of respective corner portions is arranged obliquely so that they radiate out from the center portion of the wiring board 2.

The extending direction of the bonding leads 2mbc is therefore perpendicular to neither the side 1d nor the side 1e of the semiconductor chip 1.

Such an arrangement can therefore prevent short-circuit between two bonding leads 2m adjacent to each other. As a result, multi-pin connection of a semiconductor device can be achieved.

The bonding leads 2m of the inner periphery lead group 2mb each extend along a direction crossing with (almost perpendicular to) the end portion of an inside solder resist film (inner insulating film) 2ca which is a portion of an insulating film covering a portion of the bonding leads 2m.

This means that all the bonding leads 2m of the inner peripheral lead group 2mb are arranged on each side of the inner solder resist film 2ca having a substantially square shape so as to be perpendicular to the side (end portion). This makes it possible to make exposure lengths of the bonding leads 2m of the inner periphery lead group 2mb from the inside solder resist film 2ca almost equal to each other. This also applies to the bonding leads 2m of the outer periphery lead group 2ma. They are arranged so that the exposure lengths of the bonding leads 2m arranged in the opening portion 2k from the solder resist film 2c are made substantially equal to each other.

Even if solder precoats are formed on the bonding leads 2m, the leads can be precoated with a substantially equal amount of a solder and therefore, solder precoats having a substantially equal height can be formed.

As a result, uniform solder wetness can be achieved during flip chip bonding.

### Modification Example 2

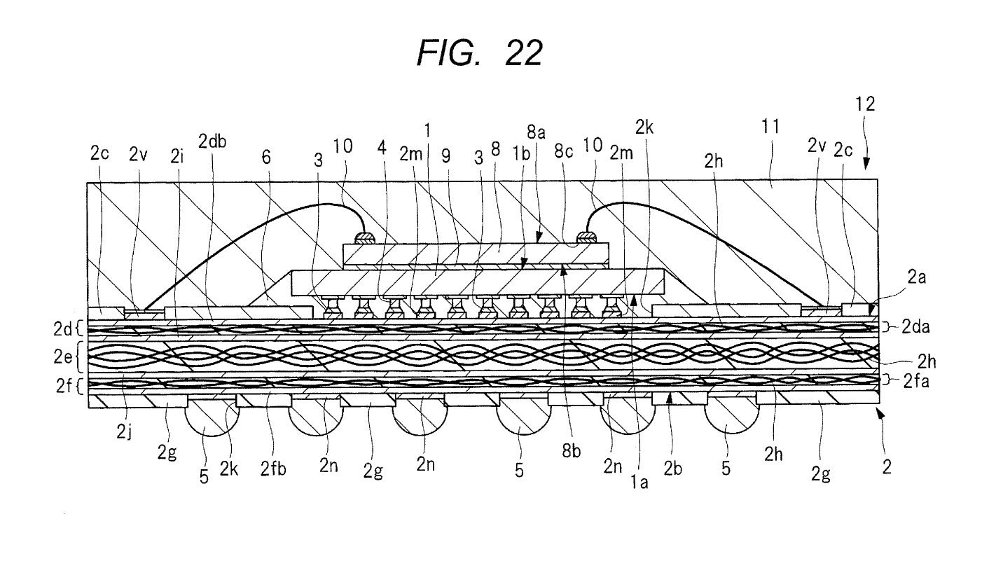

FIG. 22 is a cross-sectional view showing one example of the structure of a semiconductor device of Modification Example 2 of the embodiment.

The semiconductor device of Modification Example 2 is a chip stack type semiconductor device. In this semiconductor device, on a semiconductor chip 1 flip chip bonded to a wiring board 2, another semiconductor chip 8 is mounted and the semiconductor chip 8 on the upper side is electrically connected with the wiring board 2 via wires.

The wiring board 2 has, on the side of the lower surface 2b, a plurality of solder balls 5 as an external terminal. Therefore, the semiconductor device shown in FIG. 22 is also a BGA 12.

In the BGA 12, for example, the semiconductor chip 1 on the lower side is a controller chip, while the semiconductor chip 8 on the upper side is a memory chip. Therefore, it is also a SIP (system in package) type semiconductor device in which the semiconductor chip 8 on the upper side is controlled by the semiconductor chip 1 on the lower side. The semiconductor chip 1 and the semiconductor chip 8 may however be a semiconductor chip having another function.

The semiconductor chip 8 on the upper side is attached, with a die bonding material 9, onto the back surface 1b of the semiconductor chip 1 on the lower side with the main surface 8a up. Therefore, the back surface 1b of the semiconductor chip 1 on the lower side and the back surface 8b of the semiconductor chip 8 on the upper side are bonded to each other with the die bonding material 9.

A pad 8c on the main surface 8a of the semiconductor chip 8 and a bonding lead 2v on the upper surface 2a of the wiring board 2 are electrically connected with each other via a wire (conductive member) 10. The wire 10 is a gold wire or a copper wire.

The semiconductor chip 1 on the lower side is, similar to the BGA 7 of the embodiment, flip chip connected with a plurality of bonding leads 2m of the wiring board 2 via conductive members such as a plurality of copper pillars 4. This flip chip connection is protected with an underfill 6 and the back surface 1b of the semiconductor chip 1, the semiconductor chip 8, and the plurality of wires 10 are molded with a molding member 11 made of a molding resin. The molding resin that constitutes the molding member 11 is, for example, an epoxy-based thermosetting resin.

The wiring board 2 of the BGA 12 of Modification Example 2 is similar to the wiring board 2 of the BGA 7 of the embodiment and an insulation layer 2d has thereon a plurality of bonding leads 2m. This insulation layer 2d is comprised of a prepreg (resin layer) 2da having a glass cloth (glass fibers) 2h and a resin layer 2db formed (stacked) on the prepreg 2da and not having the glass cloth 2h.

Therefore, the each of bonding leads 2m contacts with the resin layer 2db and arranged on this resin layer 2db. This means that the bonding leads 2m are supported by the resin layer 2db having lower hardness and softer than the prepreg 2da.

The bonding leads 2m each has therebelow the soft resin layer 2db so that similar to the BGA 7 of the embodiment, even when a load is imposed on the bonding leads 2m from the copper pillars 4 at the time of flip chip bonding, a stress caused by variations in height of electrodes can be absorbed by sinking of the soft resin layer 2db, making it possible to reduce the stress applied to the semiconductor chip 1.

As a result, damage done to the semiconductor chip 1 can be reduced and inconvenience such as formation of cracks in the semiconductor chip 1 or exfoliation of a surface protective film can be prevented. In short, damage of the semiconductor chip 1 in flip chip bonding can be reduced or prevented. This makes it possible to improve the reliability of the semiconductor device (BGA 12).

The other advantages available by the BGA 12 and fabrication thereof are similar to those of the BGA 7 of the embodiment so that an overlapping description is omitted.

### Modification Example 3

In the above embodiment, a description was made on using, for example, a material composed mainly of copper (Cu) as a columnar or protruding conductive member that electrically connects the semiconductor chip 1 with the wiring board 2, but the material is not limited thereto. As a material softer than copper (Cu), for example, a material composed mainly of gold (Au) may be used.

When gold (Au) and copper (Cu) are compared, a conductive member made of gold is itself easily deformable (easily flattened) so that the electrodes (bonding leads 2m) of the wiring board 2 are not necessarily supported by a two-layered insulation layer used as an insulation layer that supports the electrodes (bonding leads 2m) of the wiring board 2. In other words, a material (for example, prepreg) harder than the resin layer not containing the glass cloth (glass fibers) 2h can be used as an insulation layer that supports the electrodes (bonding leads 2m) of the wiring board 2.

A deformation amount (flattened amount) of the conductive member however becomes large when the height of the conductive members or electrodes (bonding leads) varies greatly. When extreme deformation of the conductive member is not desired, using the wiring board 2 having an insulation layer with a constitution similar to that of the above embodiment is preferred even if the conductive member is made of a material composed mainly of gold (Au).

### Modification Example 4

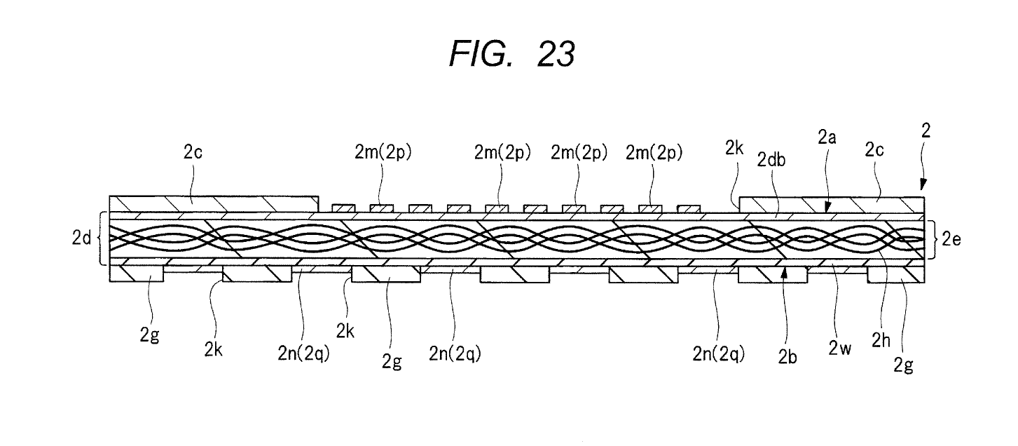

FIG. 23 is a cross-sectional view showing one example of the structure of a wiring board to be incorporated in a semiconductor device of Modification Example 4 of the embodiment.

Modification Example 4 shows a modification example of a wiring board to be incorporated in a semiconductor device. The wiring board 2 shown in FIG. 23 is a so-called two-layered board having two wiring layers. It has a wiring layer 2p on the surface side of a core layer (prepreg) 2e and a wiring layer 2q on the back surface side of the core layer 2e.

Also in the wiring board 2 shown in FIG. 23, a plurality of bonding leads (electrodes) 2m formed in the wiring layer 2p have therebelow a resin layer 2db having hardness lower than that of the core layer 2e having a glass cloth 2h. Also on the side of the lower surface 2b, the wiring layer 2q having therein a plurality of lands (electrodes) 2n and the core layer 2e have therebetween a resin layer 2w having hardness lower than that of the core layer 2e.

In the wiring board 2 of Modification Example 4, therefore, an insulation layer 2d is comprised of the resin layer 2db, the core layer 2e, and the resin layer 2w. The bonding leads 2m are supported by the soft resin layer (layer not having a glass cloth) 2db, while the lands 2n are supported by a soft resin layer (layer not having a glass cloth) 2w.

Also in the wiring board 2 of Modification Example 4 having a two-layered wiring structure according to Modification Example 4, the bonding leads 2m have therebelow the soft resin layer 2db. Similar to the BGA 7 of the embodiment, when a load is applied to the resin layer 2db via the bonding leads 2m at the time of flip chip bonding, deformation of the resin layer 2db and sinking of the bonding leads 2m occur. As a result, even if there occur variations in the height of copper pillars 4, all the copper pillars 4 can be connected with the bonding leads 2m. This means that even the copper pillars 4 having low height can be connected with the bonding leads 2m.

As described above, the bonding leads 2m of the wiring board 2 that are connected with, among the copper pillars 4, copper pillars having a height greater than the other copper pillars 4 sink so that formation of a crack 67 (refer to FIG. 26) in the insulation layer immediately below the pads 1c of the semiconductor chip 1 on which the copper pillars 4 having a greater height are formed can be prevented. This makes it possible to improve the reliability of the BGA 7.

Further, even when a stress is applied to the solder balls 5 of the semiconductor device (BGA 7) or the like, the stress can be relaxed by the soft resin layer 2db and direct propagation of damage to the flip chip connection can be prevented.

In short, even when a stress such as thermal stress is applied to the solder balls 5, the bonding leads 2m with which the copper pillars 4 are connected have therebelow the soft resin 2db so that the stress can be relaxed and absorbed by the deformation of the soft resin layer 2db so as to prevent direct propagation of damage to the flip chip connection or the semiconductor chip 1.

As a result, generation of connection failures of the flip chip connection can be suppressed.

The other advantages available by the above semiconductor device and fabrication thereof are similar to that of the BGA 7 of the embodiment so that an overlapping description is omitted.

### Modification Example 5

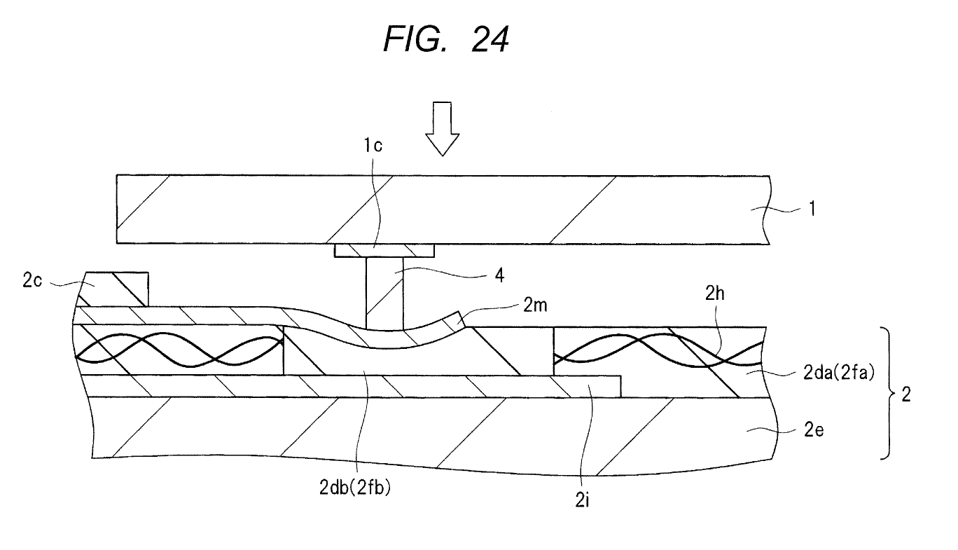

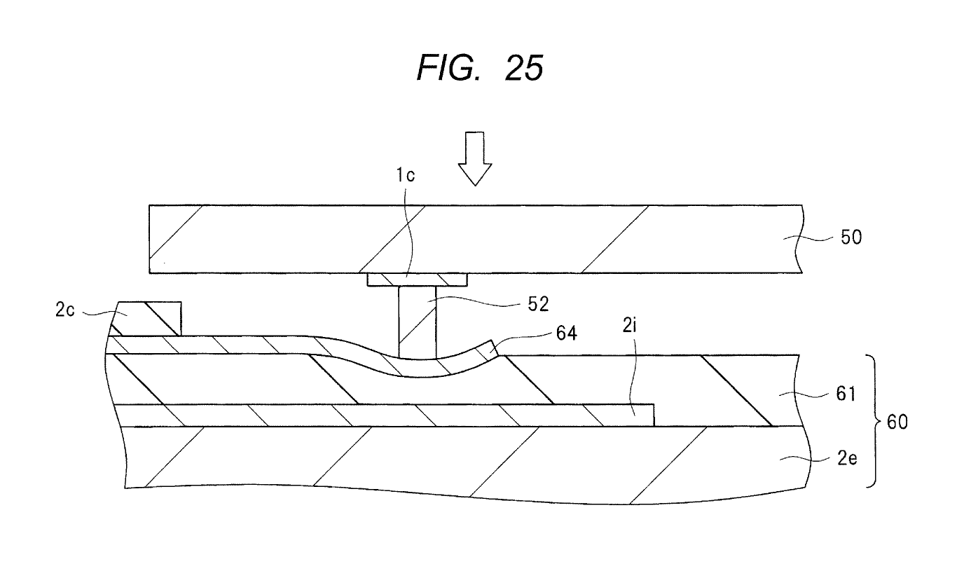

With regards to the positional relationship among the resin layers 2db and 2fb not containing a glass cloth and the resin layers (prepregs 2da and 2fa) containing the glass cloth 2h, the structure of them is not limited to the stacking structure as described above in the embodiment. As shown in FIG. 24, the resin layers 2db and 2fb not containing a glass cloth may be provided only immediately below the electrodes (bonding leads 2m) with which columnar (or protruding) conductive members (copper pillars 4) are to be connected.

It is however preferred to employ a stacking structure in which layers (resin layers) 2da, 2db, 2fa, and 2fb have been stacked one after another as described in the embodiment when a manufacturing efficiency (number of steps) of the wiring board 2 is taken into consideration.

### Modification Example 6

In the above embodiment, BGA has been described as one example of a semiconductor device. The semiconductor device is however not limited to BGA and it may be LGA (land grid array) having, on the surface of a land thereof, a conductive member.

### Modification Example 7

Further, the modification examples can be used in combination without departing from the scope of the technical concept described in the above embodiment.

What is claimed is:

1. A semiconductor device, comprising:
a wiring board having a first insulation layer, a plurality of bonding leads formed over a first surface of the first insulation layer, and a plurality of lands formed over a second surface of the first insulating layer opposite to the first surface, and
a semiconductor chip having a first main surface, a plurality of pads formed over the first main surface, and a second main surface opposite to the first main surface, and mounted over the first surface of the wiring board via a plurality of conductive members such that the first main surface faces the first surface of the wiring board;
wherein the conductive members are electrically connected with the bonding leads of the wiring board, respectively, via a plurality of solder materials,
wherein the first insulation layer has a first resin layer having glass fibers, and a second resin layer having no glass fibers, and
wherein each of the bonding leads contacts with the second resin layer.

2. The semiconductor device according to claim 1,
wherein the second resin layer has a thickness less than that of the first resin layer.

3. The semiconductor device according to claim 2,
wherein the conductive members each has material having copper as a main component thereof.

4. The semiconductor device according to claim 3,
wherein the conductive members are each columnar.

5. A method of manufacturing a semiconductor device, comprising the steps of:
(a) providing a wiring board having a first insulation layer, a plurality of bonding leads formed over a first surface of the first insulation layer, and a plurality of lands formed over a second surface of the first insulating layer opposite to the first surface,
wherein the first insulation layer has a first resin layer having glass fibers, and a second resin layer having no glass fibers, and
wherein each of the bonding leads contacts with the second resin layer;
(b) after the step (a), disposing a semiconductor chip over the first main surface of the wiring board via a plurality of conductive members such that a first main surface of the semiconductor chip faces the first surface of the wiring board, the semiconductor chip having the first main surface, a plurality of pads formed over the first main surface, and a second main surface opposite to the first main surface; and
(c) after the step (b), applying a load to the semiconductor chip in a thickness direction of the wiring board, thereby electrically connecting the conductive members with the bonding leads, respectively.

6. The method of manufacturing a semiconductor device according to claim 5,
wherein the second resin layer has a thickness less than that of the first resin layer.

7. The method of manufacturing a semiconductor device according to claim 6,
wherein each of the conductive members has a material having copper as a main component thereof.

8. The method of manufacturing a semiconductor device according to claim 7,
wherein prior to the step (c), the conductive members each has, on the end surface thereof, a solder material, while the bonding leads of the wiring board have, on the surface thereof, no solder material.

9. The method of manufacturing a semiconductor device according to claim 8,
wherein the wiring board is formed by overlapping the first insulation layer, a first wiring layer constituting the bonding leads, and a second wiring layer constituting the lands with each other, followed by contact bonding.

10. The method of manufacturing a semiconductor device according to claim 9,
wherein the conductive members are each columnar.
